(19) United States
(12) Patent Application Publication
(10) Pub. No.: US 2024/0310590 A1
(43) Pub. Date: Sep. 19, 2024

(54) SEMICONDUCTOR LASER CHIP FOR PHOTONIC WIRE BONDING

(71) Applicant: Freedom Photonics LLC, Goleta, CA (US)

(72) Inventors: Gordon Barbour Morrison, Summerland, CA (US); Juergen Franz Musolf, Santa Barbara, CA (US); Victoria Marie Rosborough, Santa Barbara, CA (US); Leif Albin Johansson, Santa Barbara, CA (US); Thomas Zhongyong Liu, Santa Clarita, CA (US)

(21) Appl. No.: 18/604,159

(22) Filed: Mar. 13, 2024

Related U.S. Application Data
(60) Provisional application No. 63/490,081, filed on Mar. 14, 2023.

(51) Int. Cl. G02B 6/42; H01S 5/02345; H01S 5/026

(52) U.S. Cl. CPC G02B 6/425; H01S 5/02345; H01S 5/026

(57) ABSTRACT

Method and designs for optical systems formed by optically connecting active optical devices mounted on carrier chip in a p-side down configuration to other optical devices using photonic wires are disclosed.

### INCORPORATION BY REFERENCE TO ANY PRIORITY APPLICATIONS

This application claims the benefit of priority of U.S. Provisional Application No. 63/490,081 titled “SEMICONDUCTOR LASER CHIP FOR PHOTONIC WIRE BONDING” (Docket No. FREDOM.036PR), which was filed on Mar. 14, 2023, the entire disclosure of which is expressly incorporated herein by reference.

### BACKGROUND

### Technical Field

Various embodiments of this application relate to fabricating, integrating, and optically connecting active chip having active layer such as laser diode or optical amplifier chips, and in particular, photonic wire bonding of such optical element (e.g., laser diode chips, optical amplifier chips, etc.) to optical waveguides.

### Description of the Related Art

In optical telecommunication applications, optical sources are optically connected to optical fibers, on-chip integrated waveguides, or other optical devices. Typically, the optical source and optical devices are fabricated on separate chips having different material compositions. Low loss optical power transfer between such optical sources and receiving optical devices fabricated on separate chips is important for supporting high quality data transfer.

### SUMMARY

Various methods and designs described herein, may be used to fabricate laser or optical amplifier chips and/or optically connect them to optical devices using polymer waveguides (e.g., photonic wires) fabricated using photonic wire bonding. For example, a laser or an optical amplifier chip may be designed to facilitate optically connecting an active waveguide of the laser chip or the optical amplifier chip to a waveguide of the optical device where the laser chip or the optical amplifier chip is mounted p-side down on the carrier chip, e.g., to improve thermal transport from an active layer of the optical amplifier or laser chip to the carrier chip.

In some aspects, the techniques described herein relate to an optical system including an active optical chip optically connected to an optical device via a photonic wire, wherein the active optical chip is mounted on a carrier chip, the active optical chip including: a substrate layer; an active layer between the substrate layer and the carrier chip, wherein a major surface of the active layer includes an edge region; and an active waveguide within the active layer, the active waveguide having an active port closer to the edge region, the active port connected to a first end of the photonic wire, wherein the active waveguide is extended in a longitudinal direction from the active port away from active port; wherein a thickness of an end of the carrier chip closer to the active port or a thickness of the substrate layer above the edge region is configured to allow a waist of a focused light beam to be positioned at the active port without optically interfering with any portion of the carrier chip or the substrate layer, respectively.

In some aspects, the techniques described herein relate to an optical system including an active optical chip optically connected to an optical device via a photonic wire, wherein the active optical chip and the optical device are mechanically connected to a common frame, the active optical chip including: a substrate layer; an active layer between the substrate layer and a carrier chip; and an active waveguide within the active layer, the active waveguide having an active port attached to a first end of the photonic wire, wherein the active waveguide is extended in a longitudinal direction from the active port away from the active port; wherein a thickness of an end region of the carrier chip closer to the active port is configured to allow a waist of a focused light beam to be positioned at the active port without optically interfering with any portion of the carrier chip or the substrate layer.

In some aspects, the techniques described herein relate to a method of fabricating an optical assembly, the method including: providing an active photonic chip having an active layer and a substrate; providing a fiber optic array; mounting the active photonic chip on a tailored carrier chip such that the active layer is between the substrate and the carrier chip; mechanically connecting the carrier chip and the fiber optic array to a common frame; and optically connecting active waveguides of the active layer to the optical fibers of the optical fiber array by fabricating photonic wires between individual active waveguides and individual optical fibers.

### BRIEF DESCRIPTION OF THE DRAWINGS

In the following description of the various embodiments, reference is made to the accompanying drawings which form a part hereof, and in which is shown by way of illustration various embodiments of the device. It is to be understood that other embodiments may be utilized and structural changes may be made.

FIG. 1 is a diagram illustrating an example optical system formed on a carrier chip including an active chip (e.g., a laser or optical amplifier chip) optically connected to an optical device via a photonic wire, where a substrate layer of the active chip is between the active layer of the active chip and the carrier chip (p-side up configuration).

FIG. 2A is a diagram illustrating a configuration for optically connecting an active chip to an optical device on a carrier chip using photonic wire, where an active layer of the active chip is between the substrate layer of the active chip and the carrier chip (p-side down configuration).

FIG. 2B is a diagram illustrating a configuration for optically connecting an active chip having a patterned substrate layer to an optical device on a carrier chip using photonic wire, where an active layer of the active chip is between the substrate layer of the active chip and the carrier chip (p-side down configuration).

FIG. 2C is a diagram illustrating a configuration for optically connecting an active chip having a patterned substrate layer to an optical device on a patterned carrier chip using photonic wire, where an active layer of the active chip is between the substrate layer of the active chip and the carrier chip (p-side down configuration).

FIG. 2D is a diagram illustrating a configuration for optically connecting an active chip mounted on a tailored carrier chip to an optical device using a photonic wire, where an active layer of the active chip is between the substrate layer of the active chip and the carrier chip (p-side down configuration).

FIG. 3 is a three-dimensional view of a portion of the configuration shown in FIG. 2C.

FIG. 4 schematically illustrates a lateral cross-section of an active chip having a patterned substrate for facilitating fabrication and/or connecting a photonic wire to an active port of an active waveguide of the active chip.

FIG. 5A schematically illustrates a longitudinal cross-section of the active chip having a patterned substrate.

FIG. 5B schematically illustrates a lateral cross-section of the active chip shown in FIG. 5A.

FIG. 5C schematically illustrates a top view (substrate side) of a wafer that includes several active chips having patterned substrates.

FIG. 6 schematically illustrates a longitudinal cross-sectional view (top) and a side cross-sectional view (bottom) of an active chip having patterned substrate that includes a height measurement hole.

FIG. 7A is a diagram illustrating a configuration for optically connecting an active chip having a patterned substrate layer supported by a polymer layer, to an optical device on a carrier chip using a photonic wire, where an active layer of the active chip is between the substrate layer of the active chip and the carrier chip (p-side down configuration).

FIG. 7B illustrates a top view (substrate side) of a wafer that includes several active chips having a patterned substrate supported by a support layer.

FIG. 8A illustrates a side view of an optical assembly including a laser array (or optical amplifier array) chip optically connected to an optical fiber array via a plurality of photonic wires, where the laser array chip is mounted on a tailored carrier chip in a p-side down configuration.

FIG. 8B illustrates a three-dimensional (3D) close up view of the optically connected (photonic wire bonded) laser array chip and an optical fiber array of the optical assembly shown in FIG. 8A.

FIG. 8C illustrates a side cross-sectional view of a connector assembly to support the optical connection between the laser array chip and the optical fiber array shown in FIGS. 8A and 8B.

FIG. 8D illustrates a top view of the connector assembly shown in FIG. 8C.

FIG. 8E illustrates a bottom view of the connector assembly shown in FIG. 8C.

FIG. 8F illustrates a three-dimensional view of the connector assembly shown in FIG. 8C.

### DETAILED DESCRIPTION

Although certain preferred embodiments and examples are disclosed below, inventive subject matter extends beyond the specifically disclosed embodiments to other alternative embodiments and/or uses and to modifications and equivalents thereof. Thus, the scope of the claims appended hereto is not limited by any of the particular embodiments described below. For example, in any method or process disclosed herein, the acts or operations of the method or process may be performed in any suitable sequence and are not necessarily limited to any particular disclosed sequence. Various operations may be described as multiple discrete operations in turn, in a manner that may be helpful in understanding certain embodiments; however, the order of description should not be construed to imply that these operations are order dependent. Additionally, the structures, systems, and/or devices described herein may be embodied using a variety of techniques including techniques that may not be described herein but are known to a person having ordinary skill in the art. For purposes of comparing various embodiments, certain aspects and advantages of these embodiments are described. Not necessarily all such aspects or advantages are achieved by any particular embodiment. Thus, for example, various embodiments may be carried out in a manner that achieves or optimizes one advantage or group of advantages as taught herein without necessarily achieving other aspects or advantages as may also be taught or suggested herein. It will be understood that when an element or component is referred to herein as being “connected” or “coupled” to another element, it can be directly connected or coupled to the other element or intervening elements may be present therebetween. For clarity of description, “reflector” or “mirror” can be used interchangeably to refer to an optical element and/or a surface having a reflectivity greater than or equal to about 5% and less than or equal to 100%. For example, an optical element and/or a surface having a reflectivity greater than or equal to about 5% and less than or equal to 99%, greater than or equal to about 10% and less than or equal to 90%, greater than or equal to about 15% and less than or equal to 80%, greater than or equal to about 20% and less than or equal to 70%, greater than or equal to about 30% and less than or equal to 60%, or any value in any range/sub-range defined by these values can be considered as a reflector or mirror. It will be understood that “light having single wavelength”, “light beam having single wavelength”, “laser light having single wavelength”, “single wavelength light” or “single wavelength laser light”, can be light comprising wavelengths within a continuous wavelength or frequency band (e.g., a narrowband) centered at a center wavelength (or center frequency).

### Introduction

In some cases, a light source (e.g., a semiconductor laser) or an optical amplifier fabricated on a chip, may be optically connected to an optical device (e.g., an optical device fabricated on another chip), using a coupling waveguide (chip-to-chip coupling waveguide). In some cases, a first end of the coupling waveguide can be connected to a facet or port (e.g., output port or output facet) of the light source and a second end of the coupling waveguide can be connected to a facet or a port (e.g., input port or input facet) of a waveguide of the optical device (herein referred to as device waveguide). In some cases, the coupling waveguide can be an individually fabricated polymer waveguide. In some such cases, a polymer waveguide can be an in-situ structured waveguide. For example, a polymer waveguide may be structured using additive three-dimensional nanofabrication techniques. In particular, in some cases the polymer waveguide may be a directly written (e.g., using a light or a focused light beam) polymer waveguide commonly referred to as a photonic wire waveguide or photonic wire (PW). Such photonic wires may be air-cladded. In some cases, after fabrication, an air-cladded photonic wire may be embedded in a low index cladding material (e.g., a low index polymer) having a lower index of refraction than the photonic wire waveguide. In some cases, a photonic wire may be a freeform waveguide with customized shape and cross-section. In some such cases, at least a portion of the photonic wire can be a single mode waveguide. A photonic wire (PW) may enable highly efficient optical power transfer from the output port of the light source to the input port of the device waveguide, while allowing a distance and a high degree of misalignment between, e.g., an output port of a light source and an input port of the optical device. For example, the photonic wire may transmit 10% to 30%, 30% to 50%, 50% to 70%, 70% to 80%, or 80% to 99%, or 99.9 to 99.99% of the optical power output via the output port of the light source to the input port of the optical device, or any range formed by any of these values, while the output port of the light source and the input port of the optical device are separated by a distance (e.g., a lateral or longitudinal distance) between 10-30 microns, 30-50 microns, 50-100 microns, 100-150 microns, 150-200 microns, 200-500 microns, or any range formed by any of these values or may be possibly longer or shorter.

A directly written polymer waveguide or photonic wire can have a diameter (e.g., an average diameter) between 0.5 to 1 microns, 1 to 2 microns, 2 to 4 microns or any range formed by any of these values.

In some implementations, a directly written polymer waveguide may be polymer waveguide formed by three-dimensional photolithography using a precisely controlled focused laser beam.

In some cases, an optical output mode of the light source (e.g., laser diode) can be different from an optical mode supported by the input port of the device waveguide and the PW may be shaped to support highly efficient optical power transfer from the light source to the device waveguide. For example, a shape of the first end of the PW connected to the output port of the light source may be tailored to support efficient optical coupling between the optical output port and the PW and a shape of the second end of the PW connected to the input port of the device waveguide may be tailored to support efficient optical coupling between the PW and the input port. In some such examples, a shape (e.g., a cross-sectional shape) of the PW may change along the length of the polymer waveguide to support low loss transmission of optical power from the first end to the second end of the PW.

Optical coupling to an optical amplifier using a PW may also be possible. Accordingly, in any of the examples and/or configurations described above or elsewhere herein, the light source can instead be another type of active optical element such as an optical amplifier. For example, light may be coupled into the optical amplifier by a PW. Likewise, other optical elements having active layers may also be employed in place of a semiconductor laser or a semiconductor optical amplifier.

In some cases, fabrication of PWs between closely spaced optical devices and/or at the optical ports that are located within or below structures that can block or optically distort at least a portion of a focused laser beam used for fabricating the PW can be challenging. For example, when the active layer of an optical source or an optical amplifier is bonded to a substrate to improve heat dissipation from the active layer, a substrate layer above the active layer may not allow unobstructed optical access to an optical port of the corresponding active waveguide for connecting a PW to the optical port. In various implementations, an optical port may comprise a facet, e.g., a cleaved facet, or an end of a waveguide configured to couple light into or out of the waveguide. Various optical devices and structures disclosed herein are designed to enable fabricating and/or connecting a PW at an output port that is located very close to the surface of a substrate and/or below a thick dielectric structure. For example, the output face of a laser chip in various implementations described herein has its p-side or optical gain active layer bonded, e.g., directly bonded, to a carrier (e.g., to facilitate heat transport to the from the optical mode region to the carrier).

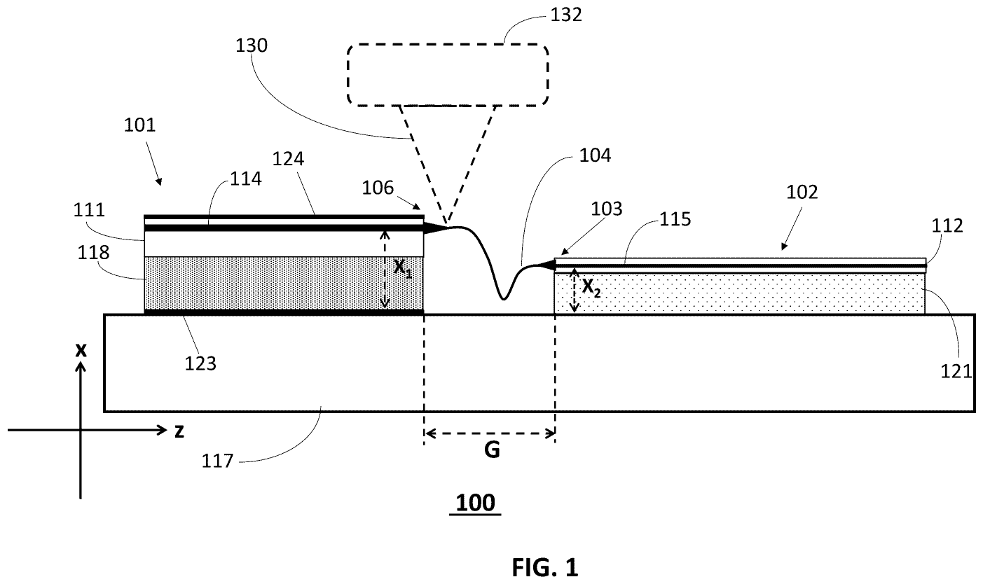

FIG. 1 is a diagram illustrating a side cross-sectional view of an example optical system 100 formed on a carrier chip 117 (or optical bench) including an active chip 101 optically connected to an optical device 102 via a photonic wire 104, where a substrate layer 118 of the active chip 101 is between an active layer 111 of the active chip 101 and the carrier chip 117 (p-side up configuration). In some cases, the substrate 118 is in thermal contact (or thermal communication) with the carrier chip 117 (e.g., via a conductive layer 124 or an intermediate layer). In some cases, at least a portion of the substrate 118 is in direct contact with the carrier chip 117. In some cases, the substrate 118 is bonded to the carrier chip 117. In some cases, the active chip 101 can be an active optical device configured to generate or amplify light and the optical device 102 can be any passive or active optical device. In some implementations, the active chip 101 and the optical device may be mounted on or bonded to the carrier chip.

In some examples, the active chip 101 may comprise a substrate layer 118 and an active layer 111 disposed (e.g., grown) on the substrate layer 118. The active layer 111 may comprise an optical gain layer that can provide optical gain upon being pumped (e.g., by an injection current). The optical gain layer may comprise one or more semiconductor material such as a compound semiconductor material (e.g., a III-V material or layers of materials such as GaAs, InP, AlGaAs, InGaAsP, GaN, AlGaN, AlSb, and the like). The substrate layer 118 may comprise one or more semiconductor material, e.g., a semiconductor material on which the active layer 111 can be grown, including substrates that may not be lattice matched to the material, such as Si, SiC or Sapphire. The active layer 111 may include an active waveguide 114 within which light (e.g. laser light) is generated and/or amplified. In some cases, e.g., when the active chip comprises a laser, the active waveguide 114 may comprise an optical cavity or may be configured to provide optical feedback. For example, in some designs, the active waveguide 114 may include a distributed Bragg grating (DFB), a distributed Bragg mirrors (DBR), a reflective facet, a sampled grating distributed Bragg reflector (SGDBR), and the like. An active port (e.g., output port) 106 of the active waveguide 114 can be a facet (e.g., a cleaved facet) of the active waveguide 114, or an end of the waveguide 114 configured to couple light into or out of the active waveguide 114. In some cases, light generated and/or amplified within the waveguide 114 is output via the active port 106. In some other cases, the active waveguide 114 may receive light generated by another source via the active port 106. For example, when the active chip 101 comprises an optical amplifier, the active waveguide 114 may receive light generated by another optical device (e.g., the optical device 102). It should be understood that while in some of the implementations disclosed below the active chip 101 is referred to as the laser chip 101, in various implementations, the active chip 101 may comprise one or both of a light source or an optical amplifier. The optical source may comprise a laser (e.g., a semiconductor laser) or another optical source (e.g., an incoherent source of light such as a light emitting diode or LED). The laser and the LED may comprise semiconductor and/or non-semiconductor materials. The optical amplifier may comprise a semiconductor optical amplifier (SOA) or other type of optical amplifiers. In some cases, the active chip 101 may comprise a plurality of light sources (e.g., lasers) and/or a plurality of optical amplifiers. For example, the active chip 101 may comprise a laser array and/or an optical amplifier array.

The optical device 102 may comprise a device waveguide 115 disposed, formed, or embedded in a waveguide layer 112. In some cases, the waveguide layer 112 may be disposed, or formed on a device substrate 121 (e.g., a waveguide of a monolithically fabricated optical device). An device port (e.g., an input port) 103 of the device waveguide 115 can be a facet (e.g., a cleaved facet) of the device waveguide 115, or an end of the device waveguide 115 configured to couple light into or out of the device waveguide 115.

In some implementations the optical device 102 can be a silicon photonic PIC chip and the device waveguide 115 can be a silicon-on-insulator (SOI) waveguide. The device chip (optical device) 102 can be a silicon photonic PIC chip and the device waveguide 115 can be a silicon-on-insulator (SOI) waveguide.

The laser chip 101 and the device chip 102 may be mounted on or bonded to an optical bench or carrier chip 117. In various implementations, the optical device 102 can be an active or passive optical device. Accordingly, the device waveguide 115 may be a passive waveguide or an active waveguide that can provide optical gain. In the configuration shown in FIG. 1, the active chip 101 is mounted on the carrier chip 117 such that a p-side of the active chip 101 (the active layer side) is on top and the substrate layer 118 is attached, (e.g., bonded) to the carrier chip 117. In various implementations, a first conductive layer 124 (e.g., a bottom electrode) may be disposed on a top surface of the active layer 111 and a second conductive layer 123 (e.g., a top electrode) may be disposed between a bottom surface of the substrate layer 118 and top surface of the carrier chip 117. In various designs, a power supply may be connected to the first and the second conductive layers 123, 124, to provide an injection current to the active layer 111 and pump an optical gain layer therein (e.g., to amplify light or generate light within the active waveguide 114).

In some implementations, the active chip 101 and the optical device 102 may be mounted such that a distance G between the active port 106 and the device port 103 along a longitudinal direction (e.g., parallel to the active waveguide 114 and the device waveguide 115 or along z-axis) is larger than 10 microns, 20 microns, 50 microns, or 100 microns, 200 microns, 500 microns or any range between any of the values or longer or shorter. In some cases, the distance G may be between 10 microns and 50 microns, 50 microns and 100 microns, or 100 microns and 150 microns, 150 microns and 200 microns, 200 microns and 500 microns or any range formed by these values or larger or smaller lower.

In some implementations, a vertical distance X1 (perpendicular to the top surface of the carrier chip 117) between a center of the active port 106 and a top surface of the carrier chip 117, is different than a vertical distance X2 between a center of the device port 103 and a top surface of the carrier chip 117. In some cases, X1 and X2 may from 5 to 30 microns, from 30 to 60 microns, from 60 to 100 microns or any value in a range formed by these values or longer or shorter.

The active port 106 may be optically connected to the device port 103 by a photonic wire (PW) 104 having a first end connected to the active port 106 and a second end connected to device port 103. In some cases, the PW 104 may be a curved waveguide having one or more curved regions which have different curvatures. In some cases, a shape of the first end of the PW 104 may be different than a shape of its second end. In some examples, the shape of the first end may be designed according to an optical mode of the active waveguide 114 and the shape of the second end may be designed according to the optical mode of the waveguide 115. In some cases, a shape and a cross-section of the PW 104 along its length may be designed to reduce optical transmission loss between the first and the second end (e.g., optical transmission loss causes by optical mode mismatch). In some cases, a diameter of the PW 104 may be between 1 and 2 microns, 2 and 4 microns, 4 and 5 microns, 5 and 6 microns, or any range between any of these values or larger or smaller. In some cases, a lateral cross section of the PW (perpendicular to a direction of propagation of light in the PW), comprises an elliptical shape. In some cases, the elliptical shape of the PW 104 may result in two perpendicular optical axes. In some cases, light having different polarization states may propagate at different velocities along the PW 104.

In some cases, the output facet 106 and/or the input port 103 may be coated with an antireflection (AR) layer(s) (e.g., including a plurality of dielectric layers). An AR layer may be designed to reduce optical reflection at an interface between a PW 104 and the device port (e.g., optical device port) 103 or the active port 106.

In some cases, the PW 104 may be bonded to the active port 106 (or the device port 103). For example, a bond (e.g., a chemical bond) may be formed between the output port 106 of the active waveguide 114 and the first end of the PW 104, and/or the input port 103 of the device waveguide 115 and the second end of the PW.

In some examples, the first or the second end of the PW 104 that is connected to the active port 106 (or the device port 103), may cover a portion of the active waveguide 114 (or the input waveguide 115). In some such examples, the first or the second ends of the polymer PW 104 may be conformably shaped according to a shape or size of the port 103, 106 and or waveguide 114, 115 to which they are connected to.

In various implementations, the PW 104 is fabricated using a photonic wire bonder after mounting the device chip 102 and the laser chip 101 on the optical bench (e.g., carrier chip) 117. In some cases, the PW 104 may be fabricated using three-dimensional photolithography such as using a focused laser beam 130 that can be moved in three dimensions to be located precisely in three dimensions. In some cases, the focused light beam 130 (e.g., a focused laser beam) may be output by a movable optical head 132 (e.g., a lens). In some cases, a wavelength of the focused light beam can be in a wavelength range (e.g., 700 nm to 900 nm) that can cure or cross-link a polymer used to fabricate the PW, for example, via a two-photon process. In some cases, a focal length f, e.g., a vertical distance (e.g., along x-axis) between the beam waist of the focused light beam 130 and the optical head 132 can be from 50 to 100 microns, from 100 to 200 microns, from to 200 to 300 microns, from to 300 to 500 microns, or any ranges formed by these values or smaller or larger values.

To fabricate the PW 104, a gap between the device chip 102 and the laser chip 101, may be filled with a photosensitive polymer. In some cases, a layer of photosensitive polymer may be disposed on at least a portion of device chip 102 and at least a portion of the active chip 101. In some cases, photosensitive polymer may comprise PMMA, PDMS, or other types of photosensitive polymers. Subsequently, the focused laser beam 130 may be used to polymerize selected regions of the photopolymer (e.g., via two-photon photo polymerization) according to a desired shape of the PW 104. The focused laser beam 130 may have a high numerical aperture. A position of the laser head (e.g., optical head) 132 and thereby the position of waist of the focused laser beam 130 may be controlled by several micro/nano-positioners is three dimensions. In some cases, the photopolymer may be baked at an elevated temperature before and/or after photopolymerization. In some examples, the PW 104 may be an air-cladded waveguide. In some examples, the PW 104 may be encapsulated in a polymer layer after fabrication.

When the active layer 111 of the active chip 101 is pumped (e.g., electrically pumped by an injection current), heat generated in the active layer 111 can be dissipated to the carrier chip via the substrate layer 118. In some cases, e.g., when the active layer 111 comprises high power laser or optical amplifier, heat transport via the substrate layer 118 to maintain the temperature of the active waveguide 114 within below a threshold value above which the performance of the active chip is degraded below an acceptable level. As such, in these cases, it can be desirable to mount the active chip 101 on the carrier chip 117 in a manner that the active layer 111 is closer, in thermal contact, or in direct contact with the carrier chip 117 so that the efficiency or heat transport from the active layer 111 to the carrier chip is increased and/or improved. In these cases, the active layer 111 can be between the substrate layer 118 and the carrier chip 117. For example, in some cases, the active layer 111 can be in thermal contact with the carrier chip 117 (e.g., via direct contact, a conductive layer and/or an intermediate layer). Given that typically the portion of the active layer 111 that is away from or on opposite side as the substrate layer 118 comprise a p-type material (e.g., a p-type semiconductor material), bonding or mounting the active chip 101 to the carrier chip 117 via the active layer 111 or layers thereon opposite the side of the active layer opposite the substrate 118 may be referred to as a p-side down configuration.

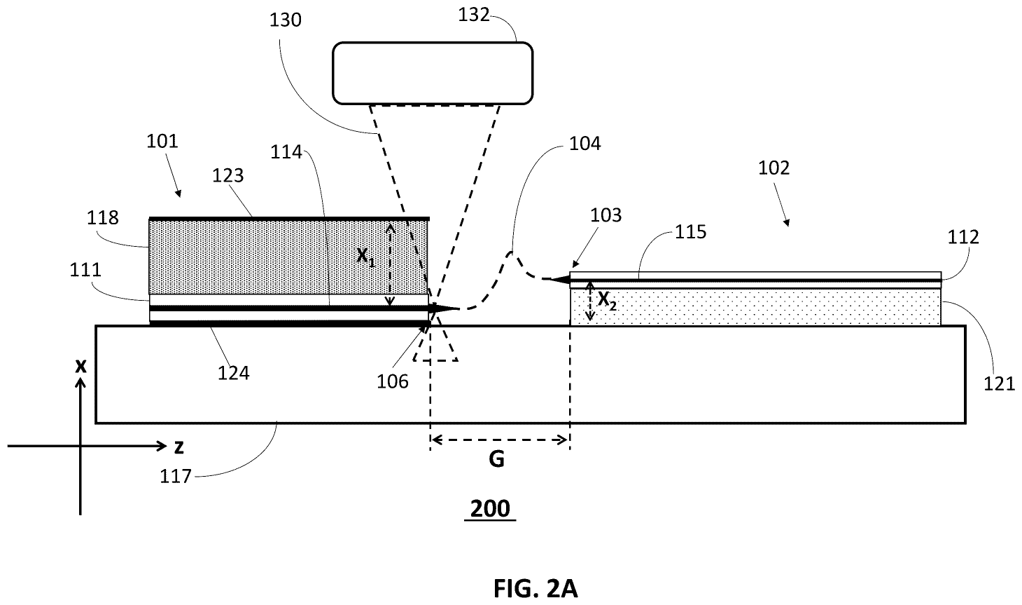

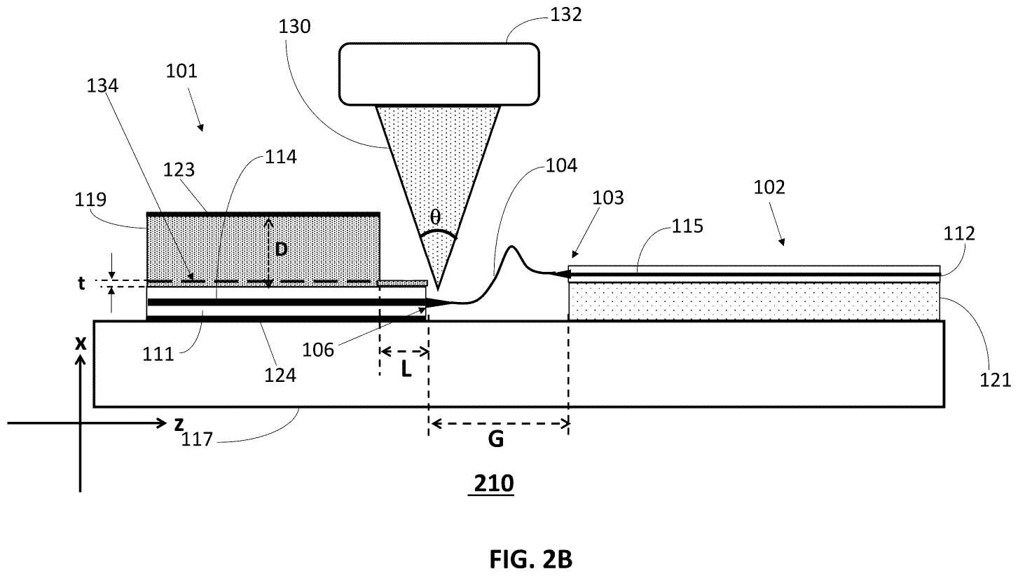

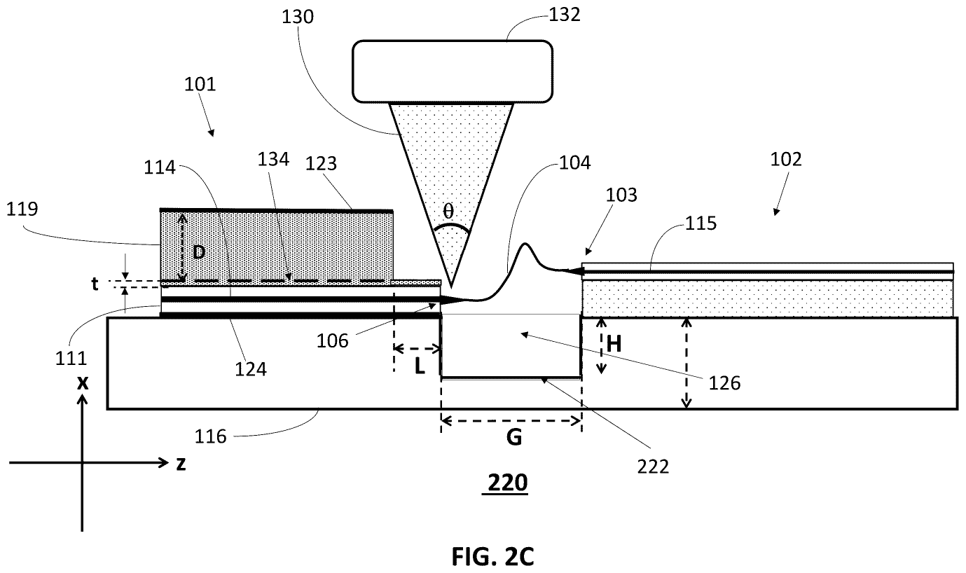

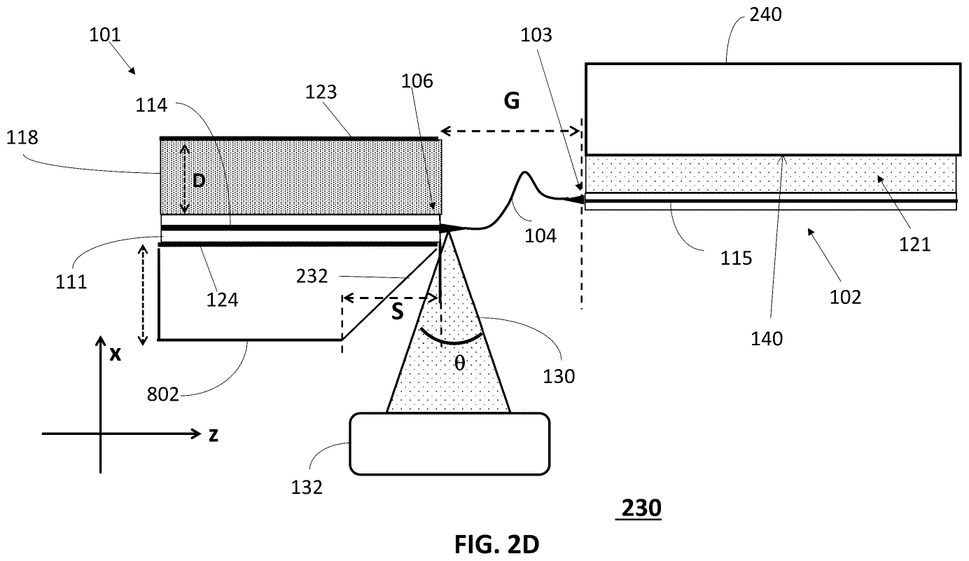

FIG. 2A schematically illustrates a side cross-sectional view of an active chip 101 mounted on its p-side on the carrier chip 117 such that the active layer 111 is between the substrate layer 118 and the carrier chip 117 such that the active layer 111 is in thermal contact with the carrier chip 117 (e.g., via the conductive layer 124 and/or an intermediate layer). In some cases, at least a portion of the active layer 111 can be in direct contact with the carrier chip 117. In some cases, the active layer 111 may be bonded to the carrier chip 117. In the configuration shown in FIG. 2A, optically connecting the active chip 101 to an optical device 102 by forming a photonic wire 104 between the active port 106 and the device port 103, can be challenging due to obstruction or interference of the focused laser beam 130 by a portion of the substrate layer 118 (e.g., a portion near the active port 106). As shown in FIG. 2A, the substrate layer 118 may block, refract, and/or diffract a portion of the focused light beam 130 resulting in an optically distorted beam that is not focused near the active port 106 and may not provide sufficient and spatially confined optical energy to form a photonic wire with the desired dimensions at and near the active port 106. By tailoring or patterning the substrate layer 118 near the active port 106, however, the quality of the focused optical beam 130 may be preserved when the optical head 132 moves a focal point of the focused light beam 130 at or near the active port 106 to form the PW 104. Moreover, in various implementations, the patterned or the tailored substrate can enable an imaging system to accurately track and control the location of the beam waist of the focused optical beam 130.

In addition to the substrate layer 118, given the short distance the waist of the focused light beam 130 and the top surface of the carrier chip 117, the carrier chip 117 may distort, disrupt and/or block at least a portion of the focused light beam 130 and reduce its intensity and/or the confinement (e.g., by diffracting and reflecting a portion of the focused light beam 130 below its waist.

In some cases, alternatively or in addition the carrier chip 117 may be patterned or tailored to reduce interference of the carrier chip 117 with the focused light beam 130 and/or allow optical access to a region near the active port 106 from below.

Accordingly, some of the active chip designs and the configurations disclosed below may be used to optically connect active optical devices (e.g., lasers and optical amplifier) that are mounted p-side down on carrier chip (for more efficient heat dissipation) to other devices mounted or formed on the carrier chip.

FIG. 2B is a diagram illustrating a configuration 210 for optically connecting an active chip 101 chip having a patterned substrate layer 119 to an optical device on a carrier chip 117 using a photonic wire, where an active layer 111 of the active chip 101 is between the patterned substrate layer 119 and the carrier chip 117 (p-side down configuration). In some cases, the active layer 111 is in thermal contact with the carrier chip 117 (e.g., via a conductive layer 124 and/or an intermediate layer). In some cases, at least a portion of the active layer 111 can be in direct contact with the carrier chip 117. In some cases, the active layer 111 is bonded to the carrier chip 117. In some cases, a bottom surface of the active layer 111 can be attached to bonded to a top major surface of the carrier chip 117 and a top major surface of the active layer 111 (also referred to as top surface) may form an interface with the patterned substrate layer 119. In some cases, above an edge region of the top surface of the active layer 111, a thickness (t) or an average thickness (tₐᵥ) of the patterned substrate 119 along a vertical direction perpendicular to the top surface of the active layer 111 (along x-axis) is smaller than a thickness (D) or an average thickness (Dₐᵥ) of the patterned substrate 119 above other regions of the top surface of the active layer 111 that are non-overlapping with the said edge region. The edge region can be extended in the longitudinal direction from the active port 106 away from the active port 106, and in a lateral direction, perpendicular to the longitudinal direction and parallel to a major surface of the active layer 111, from the active waveguide 114 toward two opposite lateral edges of the active layer 111. In some cases, the major surface of the active layer 111 can be the top surface of the active layer 111 or the interface between the active layer 111 and the patterned substrate layer 119. The thickness (D) can be a vertical distance (e.g., along or parallel to x-axis) from the interface between the active layer 111 and the patterned substrate layer 119, to a top surface of the patterned substrate 119 or to a top surface of the conductive layer 123. In various implementations, t (or tₐᵥ) is smaller than 50% of the D (or Dₐᵥ). The edge region is extended from an edge of the active layer 111 near the active port 106 away from the edge along a longitudinal direction perpendicular to the vertical direction and parallel to the active waveguide 114 (e.g., z-axis). Further, the edge region is extended from the active waveguide 114 toward two opposite lateral edges of the active layer 111, along a lateral direction perpendicular to the longitudinal direction and parallel to a major surface of the active 111 (e.g., along y-axis).

In various implementations, an area of the edge region A can be from 10 to 50 micrometer squared, from 50 to 150 micrometer squared, from 150 to 300 micrometer squared, or any ranges formed by these values or larger or smaller values. In some cases, A may be determined based at least in part on properties of the focused light beam 130 (e.g., a convergence angle, focal distance, and the like).

In some implementations, a width (W) of the edge region in a lateral direction (e.g., along y-axis) can be from 25% to 50% of D, from 50% to 75% of D, from 75% to 100% of D, from 100% to 150% of D, from 150% to 200% of D, or any ranges formed by these values or larger or smaller values.

In various implementations, the thickness D or the average thickness Dₐᵥ can be from 50 to 75 microns, from 75 to 150 microns, from 150 to 200 microns, from 200 to 500 microns, or any ranges formed by these values or larger or smaller values.

In various implementations, the thickness t or the average thickness tₐᵥ is from 0 to 1 micron, from 1 micron to 3 microns, from 3 microns to 10 microns, or any ranges formed by these values or larger or smaller values.

In various implementations, the length of the edge region (L) in the longitudinal direction can be from 25% to 50% of D, from 50% to 75% of D, from 75% to 100% of D, from 100% to 150% of D, from 150% to 200% of D, or any ranges formed by these values or larger or smaller values.

In various implementations, the lateral width (along or parallel to y-axis) of the edge region (W) in the lateral direction can be from 25 microns to 50 microns, from 50 microns to 100 microns, to from 100 microns to 500 microns, or any ranges formed by these values or larger or smaller values. In some examples, W may extend from lateral edge of the active layer 111 to an opposite lateral edge of the active layer 111. In these examples, W is substantially equal to a lateral width of the active layer 111 (W_{c}), and/or substantially equal to a lateral width of the active chip 101.

In some cases, the portion of patterned substrate layer 119 above the edge region is completely removed such that the edge region of the active layer 111 is exposed (t=tₐᵥ=0).

In some implications, the patterned substrate layer 119 may be tailored or patterned according to a shape and size of the focused light beam 130 near its focal point.

In some cases, the thickness (t) or an average thickness (2Cₐᵥ) of the substrate layer 119 above the edge region of the active layer 111 may vary along the lateral and/or the longitudinal direction.

In various implementations, the edge region can have a rectangular, square, circular, elliptical, or an irregular shape.

In some cases, the patterned substrate layer 119 may be formed starting from a non-patterned substrate layer 118 using lithographically patterned etch mask (e.g., a polymer mask) and etching (e.g., dry or wet etching). For example, first the non-patterned substrate layer 118 may be covered by a photoresist. Next, the photoresist may be lithographically patterned to remove the portion of the photoresist layer disposed above the edge region. Finally, a region of the substrate layer 111 above the edge region is etched to reduce the thickness of the substrate layer 111 to a desired value. In some cases, the patterned substrate layer 119 may comprise an etch stop layer 134 configured to be used to stop the etching process when the thickness or the average thickness of patterned substrate layer 119 above the edge region is reduced to the desired thickness.

In some cases, L, W, and/or A, may be determined such that less than 10%, less than 20%, or less than 30% (or a percentage or percentage range between or formed by any of these values), of the optical power of the focused beam of light 130 is incident on the patterned substrate layer 119 and thereby refracted, diffracted, scattered, or absorbed by the patterned substrate layer 119.

As mentioned above, in some implementations, the carrier chip 117 can be patterned or structured to further reduce obstruction, scattering, diffraction, refraction, attenuation, and/or distortion of the focused light beam 130. FIG. 2C is a diagram illustrating a configuration 220 for optically connecting an active chip 101 having a patterned substrate layer 119 to an optical device 102 mounted on a patterned or structured carrier chip 116 using a photonic wire 104, where the active chip 101 is mounted p-side down on the patterned or structured carrier chip 116. In some cases, the active layer 111 is in thermal contact with the structured carrier chip 116 (e.g., via a conductive layer 124 and/or an intermediate layer). In some cases, at least a portion of the active layer 111 is in direct contact with the structured carrier chip 116. In some cases, the active layer 111 is bonded or attached to the structured carrier chip 116. In some cases, the structured carrier chip 116 may comprise an etched region, cavity or an opening 126 positioned between the optical device 102 and the active chip 101.

In some cases, a thickness of a region of the structured carrier chip 116 between the optical device 102 and the active chip 101 may be reduced. In some cases, a length of the thin region of the structured carrier chip 116 along the longitudinal direction along z-axis can be substantially equal to a longitudinal distance (G) between the optical device 102 and the active chip 101. In some cases, the length of the thin region of the structured carrier chip 116 along the longitudinal direction along z-axis can be larger or smaller than a longitudinal distance (G) between the optical device 102 and the active chip 101. In some cases, a depth (H) of a cavity generated above the thin region can be from 5 to 10 microns, from 10 to 50 microns, from 50 to 150 microns, or any ranges formed by these values or larger or smaller values. H can be a vertical distance between a major top surface of the structured carrier chip 116 above which the optical device 102 (or the active chip 101) is mounted and the top surface 222 of the structured carrier chip 116 in the thin region.

In some examples, the active source 101 and the optical device 102 may be mounted on two separate carrier chips. The active chip 101 may be mounted p-side down on the corresponding carrier chip. In some such cases, the two separate carrier chips may be mechanically stabilized with respect to each other such that a spatial position of the active port 106 relative to the device port 103 is fixed. For example, both carrier chips may be attached to a common frame (e.g., as part of a connector assembly). In these cases, the carrier chip on which the active chip 101 is mounted may be patterned or structured to provide sufficient optical access to a region around the active port 106 such that a photonic wire 104 connected to the active port 106 can be fabricated using a focused light beam that is incident on the photonic wire bonding region from the bottom side of the carrier chip. FIG. 2D is a diagram illustrating a configuration 230 for optically connecting an active chip 101 mounted on a tailored carrier chip 802 to an optical device 102 using a photonic wire 104, where an active layer 111 of the active chip 101 chip is between the substrate layer 118 and the tailored carrier chip 802 (p-side down configuration). In some cases, the active layer 111 is in thermal contact with the tailored carrier chip 802 (e.g., via a conductive layer 124 and/or an intermediate layer). In some cases, at least a portion of the active layer 111 is in direct contact with the tailored carrier chip 802. In some cases, the active layer 111 is bonded or attached to the tailored carrier chip 802. In some cases, an edge of the tailored carrier chip 802 that is aligned with the edge of the active chip 101 near the active port 106, may be chamfered to allow positioning of the waist of the focused light beam 130 near the active port without obstructing, interfering, attenuation, diffracting, scattering, and/or distorting the focused light beam or at least reducing the amount of such obstruction, interference, attenuation, diffracting, scattering, and/or distortion of the focused light beam. The chamfered edge of the tailored carrier chip 802 may comprise a sloped surface 232. In some cases, a projection of the sloped surface 232 on a bottom surface of the active layer 111 has a length S along the longitudinal direction parallel to the waveguide 114 (along the z-axis). In some case, S can be from 50 to 100 microns, from 100 to 200 microns, from 200 to 500 microns, or any ranges formed by these values or larger or smaller values.

In some such examples, the optical device 102 to which the active chip 101 is optically connected via a photonic wire, may be positioned such that a major surface 140 of the device substrate 121 opposite to the surface on or within which the device waveguide 115 is formed, is on top and the device waveguide 115 is at the bottom side of the optical device 102. With continued reference to FIG. 2D, configuration 230 allows the focused light beam 130 to form the photonic wire 104 between the active port 106 and the device port 103 with negligible obstruction, attenuation, interference and/or distortion by the tailored carrier chip 802, the substrate 121 or the carrier chip 240. In some cases, less than 10%, less than 20%, or less than 30% (or a percentage between these values), of the optical power of the focused light beam 130 is incident on the patterned substrate layer 119 and thereby refracted, diffracted, scattered, or absorbed by the patterned substrate layer 119 by the tailored carrier chip 802, the substrate 121, or the carrier chip 240. In some examples, the tailored carrier chip 802 and the carrier chip 240, may be attached or otherwise mechanically connected to a common optical assembly (e.g., an optical connector assembly) so as to establish and/or maintain a distance between the active port 106 and the device port 103. In some examples, the optical device 102 may not include the carrier chip 240 or the substrate 121. In some examples, the carrier chip 240 comprises a V-groove, and the device waveguide 115 comprises an optical fiber waveguide placed in the V-groove.

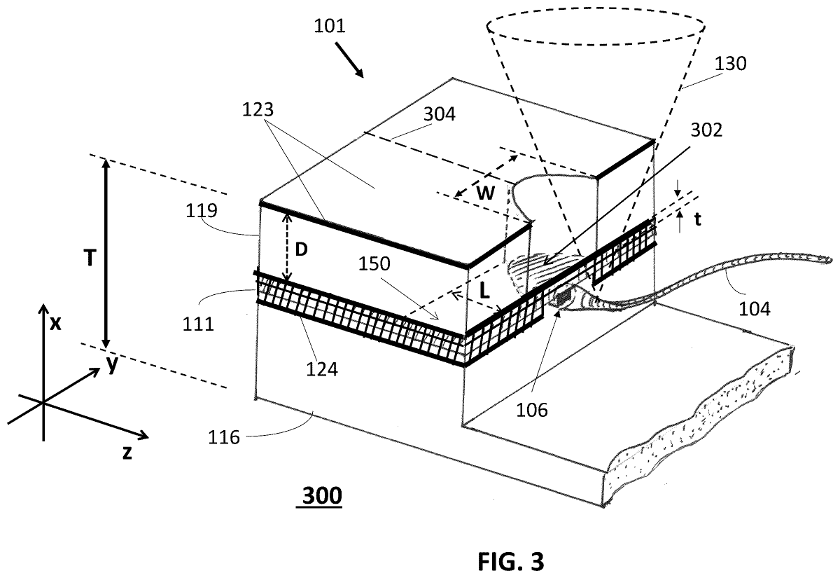

FIG. 3 illustrates a three dimensional (3D) view 300 of a portion of the configuration shown in FIG. 2C showing an active chip 101 having a patterned substrate layer 119 tailored to facilitate bonding a photonic wire 104 to the active port 106 of the active waveguide 114, where the active layer 111 of the active chip 101 is between the patterned substrate layer 119 and the structured carrier chip 116 (p-side down configuration). In some cases, the active layer 111 is in thermal contact with the carrier chip 116 (e.g., via the conductive layer 124 and/or an intermediate layer). In some cases, at least a portion of the active layer 111 is in direct contact with the carrier chip 116. In some cases, the active layer 111 is bonded to the carrier chip 116. The cross-sectional view shown in FIG. 2C can be a vertical cross-section (along x-axis) of the 3D view along the line 304.

With continued reference to FIG. 3, above an edge region 302 of the top (major) surface 150 of the active layer 111, a thickness (t) or an average thickness (fav) of the patterned substrate layer 119 along a vertical direction perpendicular to the top (major) surface 150 of the active layer 111 (along x-axis) is smaller than a thickness (D) or an average thickness (Dₐᵥ) of the patterned substrate 119 above other regions of the top (major) surface of the active layer 111 that are non-overlapping with the said edge region.

In various implementations, t (or fav) is smaller than 50% of the D (or Dₐᵥ). The edge region 302 may have any shape and is extended from the edge of the active port 106 away from the edge along the longitudinal direction parallel to the active waveguide 114 (e.g., z-axis), and along the lateral direction (e.g., y-axis) away from the active waveguide 114 toward the opposite edges of the active layer 111. In various implementations, to prevent an interaction between the focused light beam 130 and the patterned substrate layer 119, a shape, a length (L) or an average length (Lₐᵥ), and/or a width (W) or an average width (Wₐᵥ) of the edge region 302 may configured or selected based at least in part on the focal distance (f) and/or a convergence or convergence angle of the focused light beam 130 used to fabricate the PW 104. In some cases, an angle of convergence of the focused beam of light (θ) is larger than 30 degrees, larger than 45 degrees, larger than 60 degrees, larger than 75 degrees, larger than 90 degrees, or larger than 105 degrees, or any range formed by any of these values or larger than any values between these values. In some cases, a shape, size, and/or an area of the edge region may be designed such that less than 10%, less than 20%, or less than 30% (or any percentage range formed by any of these values), of the optical power of the focused beam of light 130 is incident on the patterned substrate layer 119 and thereby refracted, diffracted, scattered, or absorbed by the patterned substrate layer 119.

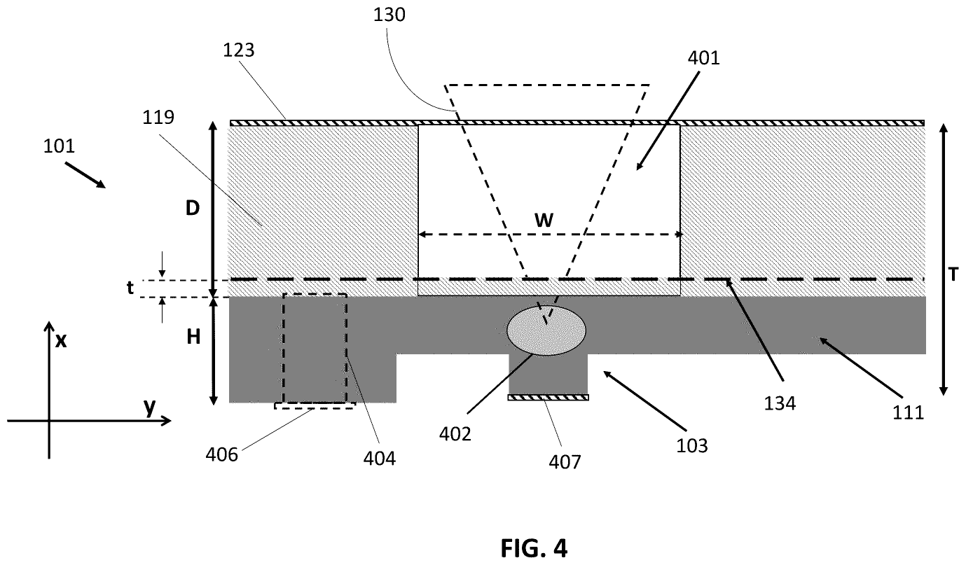

FIG. 4 schematically illustrates a front view (in the x-y plane) of the active chip 111 (e.g., active chip 111 in FIG. 3) having a patterned substrate 119 for facilitating fabrication or connecting a photonic wire to an output port 106 of an active waveguide 114 of the active chip 101. In some cases, the active chip 101 comprises a waveguide structure (e.g., a buried waveguide or a ridge waveguide) configured to optically guide at least one optical mode 402 within the active layer 111, and a patterned substrate layer 119 that includes a cavity 401 formed above the edge region 302 of the active layer 111. The cavity 401 may be formed by removing a portion of the patterned substrate layer 119 above the edge region 302 so as to reduce a thickness (t) or an average thickness (tₐᵥ) above the edge region 302 to at least less than 50% of the thickness D or average thickness (Dₐᵥ) of the substrate layer 119 above a region of the patterned substrate layer 119 that does not overlap with the edge region 302. In some cases, the substrate layer 119 may include an etch stop layer 134 configured to stop an etching process used to form the cavity 401, along the vertical direction, when the thickness (t) of the substrate layer 119 is equal or substantially equal to a target thickness. The target thickness may be determined based at least in part on part on the focal distance (f) and/or a convergence (e.g., a convergence angle) of the focused light beam 130 used to fabricate the PW 104. In some cases, a convergence angle of the focused beam of light (θ) is larger than 30 degrees, larger than 45 degrees, larger than 60 degrees, larger than 75 degrees, larger than 90 degrees, or larger than 105 degrees, or any range formed by any of these values or larger than any values between these values. In some cases, the etch stop layer 134 may be disposed at interface between the active layer 111 and the patterned substrate layer 119 such that t is substantially equal to 0.

The active chip 101 may further comprise a bottom electrode 407 (e.g., a first conductive layer) and a top electrode 123 (e.g., a second conductive layer) configured to provide an injection current to the active layer 111 in order to pump a region of the active layer 111 at and/or near the optical mode 402.

In some implementations, the top electrode 123 may be replaced by a second bottom electrode 406 that is connected to a conductive layer disposed between the active layer 111 and the patterned substrate layer 119 by vertical conducive line 404 (e.g., a conductive via).

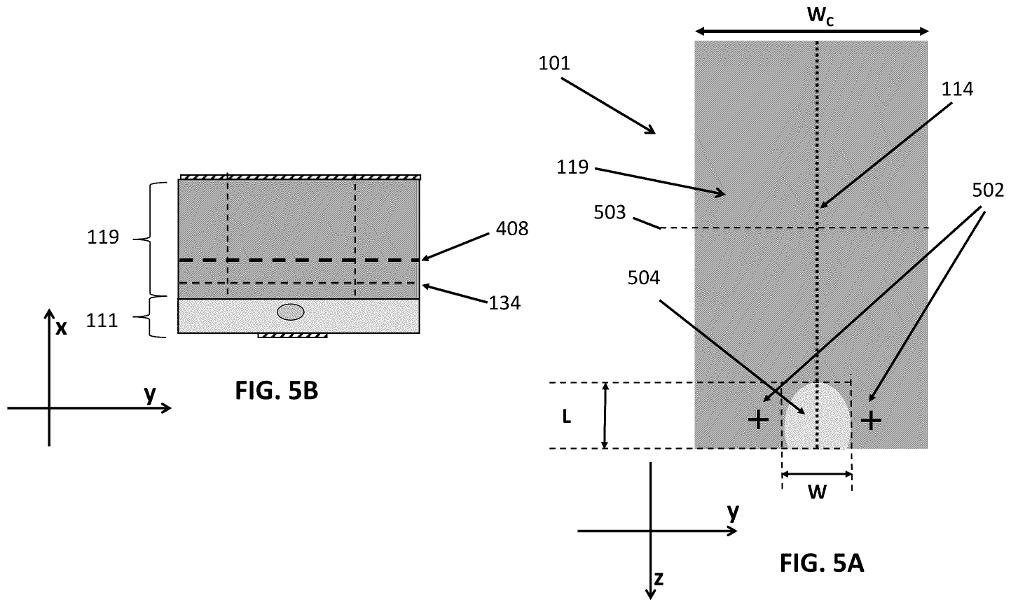

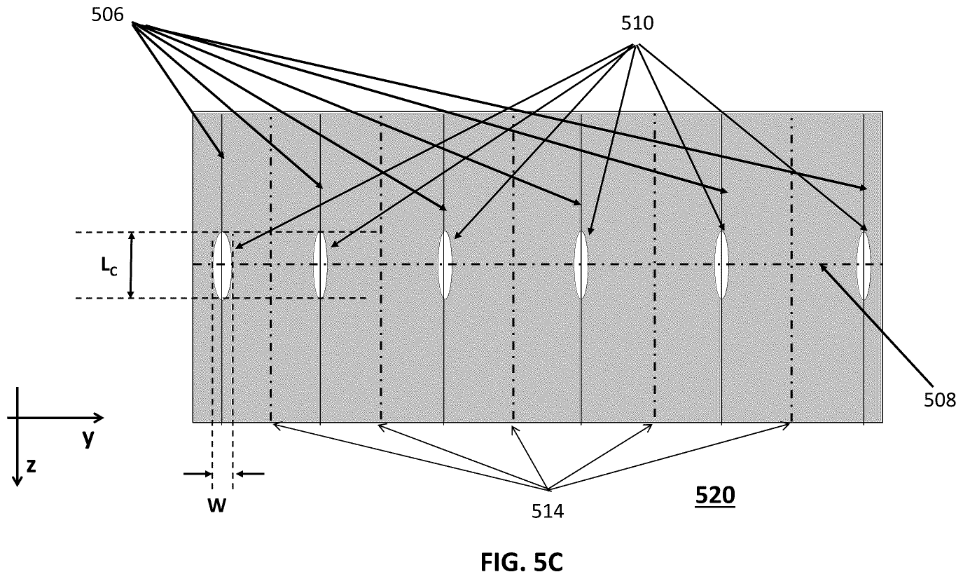

FIG. 5A schematically illustrates a top view (parallel to the z-y plane) of the active chip 101 (mounted p-side down) having a patterned substrate 119 showing a bottom surface 504 of the cavity 401. In some cases, the bottom surface 504 can be a top (major) surface of the active layer 111.

In some implementations, the bottom surface 504 corresponding to the edge region 302 of the etched portion of the substrate layer (or the active layer 111) can be symmetrically or near symmetrically positioned with respect to the active waveguide 114. In some cases, a lateral distance (along z-axis) of an edge of the exposed bottom surface from the active waveguide 114 can be substantially equal to W/2. In some cases, a lateral distance (along z-axis) of two opposite edges of the bottom (major) surface, that define the width W, from the active waveguide 114 can be substantially equal to W/2. In some cases, W can be at least 5 times, 10 times, 20 time, or 100 times, larger than a width of the active waveguide 114 or any range formed by any of these values or possibly larger or smaller. In some cases, W can be determined based on D, for example, W can be from 50% of D to 100% of D, from 100% of D to 200% of D or any ranges formed by these values or larger or smaller. In some implementations, W, L, and/or A (the area of the edge region or etched region of the substrate), may be increased proportional to D, such that less than 10%, less than 20%, or less than 30% (or any percentage range formed by these values), of the optical power of the focused beam of light 130 is incident on the patterned substrate layer 119 and thereby refracted, diffracted, scattered, or absorbed by the patterned substrate layer 119.

In some cases, at least a portion of the top (major) surface of the patterned substrate 119 may comprise a conductive region. In some cases, the top surface of the patterned substrate 119 may comprised at least two alignment marks 502. These alignment marks 502 may be defined and fabricated using lithographic techniques (e.g., IR imaging) to align them with features on the bottom surface of p-side of the active chip 101. These alignment marks 502 may be used to control and position the focused light beam 130 with respect to the active port 106 to facilitate fabricating a portion of the PW 104 at or near the active port 106.

FIG. 5B illustrates a vertical cross-section of the active chip 101 shown in FIG. 5A along the line 503. In some cases, the patterned substrate layer 119 may comprise two or more etch stop layers. For example, a first etch stop layer 408 may be used to stop a first etching process and a second etch stop layer 134 may be used to stop a second etching process after the first etching process to remove the first etch stop layer 408. In some cases, the first and the second etching processes may be used to remove layers of the patterned substrate layer 119 comprising different materials. In some examples, an etch stop layer may comprise InGaAsP, e.g., in an InP substrate, InGaP, e.g., in an GaAs substrate, GaAs, e.g., in an AlGaAs substrate, InGaAs, e.g., in an GaAs substrate, or InP in various substrates comprising quaternary or ternary layers.

FIG. 5C schematically illustrates a top view (substrate layer side) of a wafer 520 comprising several active chips 101 having patterned substrate layers, where the wafer 520 includes an active layer and a substrate layer on top of the active layer. The wafer 520 may comprise a plurality of active waveguides 506 extending along a longitudinal direction (e.g., z-axis) and a plurality of etched regions 510 where a thickness of the substrate layer 119 within the etched regions 510 is at least 10%, 15%, 20%, 50%, or 60% less than the thickness of the substrate layer outside of the etched regions 510 or any range formed by any of these values. In the example shown, the wafer 520 is divided into a plurality of lateral wafer sections where an individual lateral wafer section is defined by two consecutive longitudinal cleave lines 514, or a longitudinal cleave line and a lateral edge of the wafer. An individual longitudinal wafer section includes two active wafers and an etched region (e.g., an etched region of the plurality of etched regions 510). In some cases, the lateral cleave line 508 may divide the individual etched regions 510 and the individual active waveguides 506 to first and second etched portions, and first and second waveguide portions such that the first etched portion above the first waveguide portion and the second etched portion above the second waveguide portion provide optical access to the corresponding active ports 106 of the first and the second active waveguides, respectively (e.g., similar to configurations shown above in FIGS. 2A-2D, 3, 4, 5A). In some cases, the lateral cleave line 508 may divide an individual etched region, having a length L_{c}, into equal or substantially equal etched sections such that L_{c}/2=L.

In some cases, the individual active chips 101 (e.g., 12 active chips in this case) having patterned substrate layers 119, may be separated from the wafer 520 by cleaving the wafer 520 along a lateral cleave line 508, and along longitudinal cleave lines 514.

In some implementations, an active chip 101 may include a vertical alignment hole configured to provide optical access to a region of the top (major) surface of its active layer 111. In some, cases the vertical alignment hole may be configured to allow determining a vertical distance (e.g., along or parallel to the x-axis) of the top surface of the active layer 111 from a reference point (e.g. a reference point on the optical head 132) and thereby enable or facilitate controlling the optical head 132 to position the waist of the focused light beam 130 near or at the active port 106, e.g., when direct imaging of the active port is difficult or not possible.

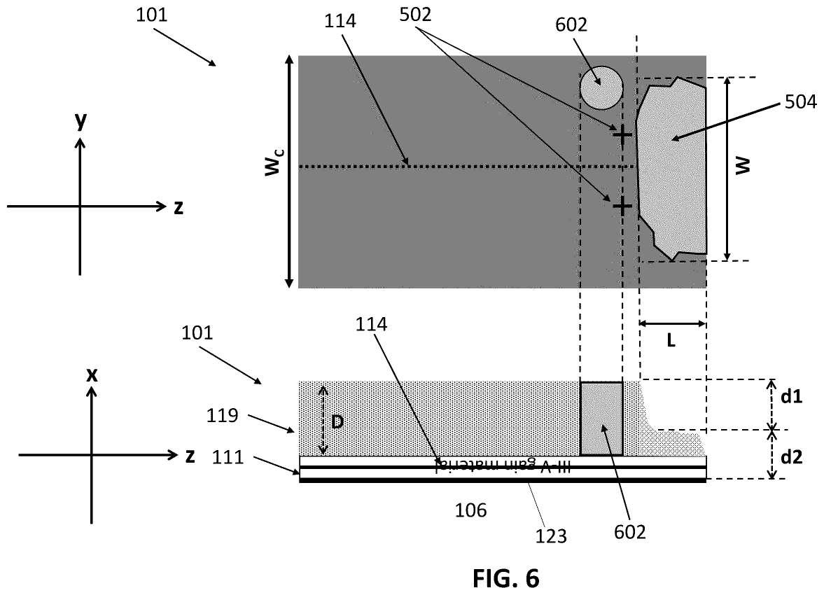

FIG. 6 schematically illustrates a longitudinal cross-sectional view (top) and a side cross-sectional view (bottom) of an active chip 101 having a patterned substrate 119 that includes a vertical alignment hole 602. In some cases, the vertical alignment hole 602 may comprise a cavity extended from the top (major) surface of the patterned substrate layer 119 to a region of the top (major) surface of the active layer 111. A lateral cross-section of the vertical alignment hole 602 can have any shape (e.g., circular, rectangular, etc.). An area of the vertical alignment hole 602 may be configured to allow an imaging system to focus on a region of the top (major) surface of the active layer 111 exposed via the vertical alignment hole 602 and thereby determine a vertical distance of the corresponding imaging head from the top (major) surface of the active layer 111. In some examples, a thickness (t) of the patterned substrate layer 119 above the edge region 302 may otherwise not allow the imaging system to image the active port 106 or otherwise determine a vertical distance between the active port 106 and the optical head 132. A thickness (t) of the patterned substrate layer 119 above the edge region 302 may be larger than a threshold amount to provide mechanical support to a portion of the active layer 111 below the edge region 302.

In these cases, the image (height information) obtained via the vertical alignment hole 602 may be used to position the waist of the focused light beam 130 at or near the active port 106 to forming and/or optically connecting the PW 104 to the active port 106.

In some cases, a vertical distance (d2) between a top (major) surface of the patterned substrate layer 119 above the edge region 302 and the bottom (major) surface of the active layer 111 can be from 0.5 to 1 micron, from 1 to 5 microns, from 5 to 15 microns, or any ranges formed by any of these values or possibly larger or smaller.

In some implementations, a lower bound for the thickness (t) or average thickness (fav) of the patterned substrate layer 119 above the edge region 302 may be limited by the mechanical stability of a portion of the active layer 111 below the edge region 302. For example, if t or tₐᵥ is smaller than a threshold value, the portion of the active layer 111 below the edge region 302 may bend down or up due to internal mechanical stress that was previously balanced by the substrate layer 119. On the other hand, a thickness (t) or average thickness (tₐᵥ) of the patterned substrate layer 119 above the edge region 302 that provides sufficient mechanical support to the portion of the active layer 111 below the edge region 302, may not provide sufficient optical access to active port 106 for fabrication of the 104 without interfering with the focused light beam 130.

In some implementations, a support layer (e.g., a polymer layer) may be disposed on a thin region of the patterned substrate layer 119 above the edge region 302, or above a region of the active layer 111 below the edge region 302, to mechanically support the region of the active layer 111 below the edge region 302 (e.g., when t or tₐᵥ is smaller than a threshold value).

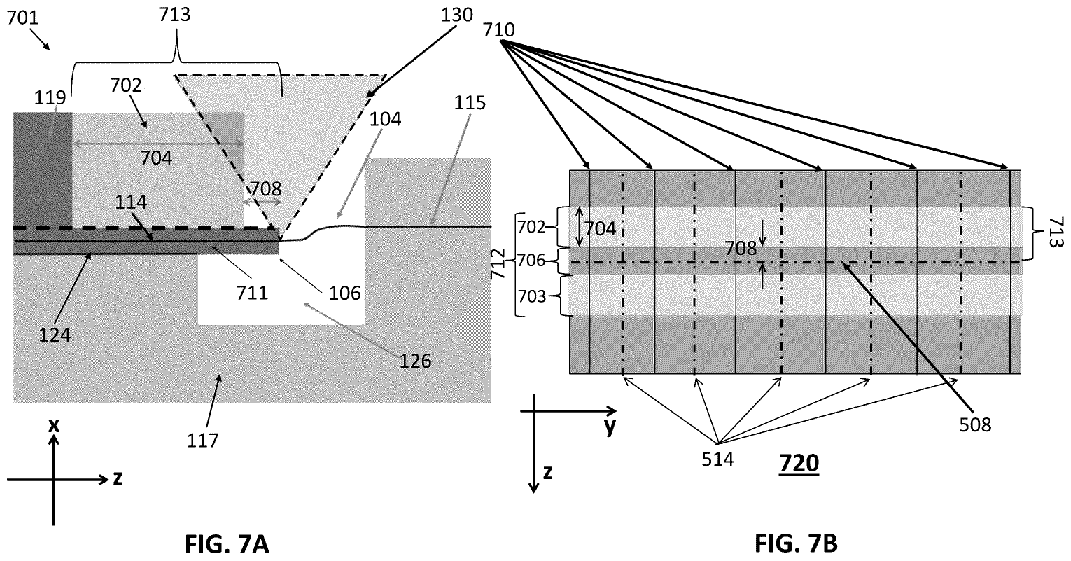

The support layer may comprise a first material having refractive index close to the refractive index of a second material used to fabricate the PW 104 to reduce or avoid optical distortion of the focused light beam 130 by diffraction or refraction near an interface between the first and the second materials. For example, a difference between the refractive index of the first and the second materials, can be less than 0.1%, less than 1%, less than 2%, less than 5%, less than 10% (or any range formed by any of these values), of the refractive index of the second material. Additionally, the support layer (first material) may have a low optical absorption at a wavelength of the focused light beam 130. In some cases, the support layer can be an optically transparent material that allows imaging the active port layer without significant optical distortion. In some cases, the support layer may comprise a polymer (e.g., a UV curable polymer) such as SU8. FIG. 7A is a diagram illustrating a configuration for optically connecting an active chip 701 having a patterned substrate layer 119 and a support layer 702, to a device waveguide 115 fabricated on a carrier chip 117 using a PW 104, where an active layer 711 of the active chip 701 is between the patterned substrate layer 119 and the carrier chip 117 (p-side down configuration). In some cases, the active layer 711 can be in thermal contact with the carrier chip 117 (e.g., via the conductive layer 124 and/or an intermediate layer). In some cases, at least a portion of the active layer 711 is in direct contact with the carrier chip 117. In some cases, active layer 711 is bonded to the carrier chip 117. In some cases, the carrier chip 117 may comprise an etched region, cavity or an opening 126 under an edge portion of the active chip 701 extending to the device waveguide 115.

In some cases, the support layer 702 may be disposed above at least a portion of the edge region of the active layer 711 and longitudinally extended from an un-etched region 713 of the patterned substrate layer 119 to an end, or close to an end, of the active chip 701 near the active port 106. A length 704 of the support layer 702 (e.g., along or parallel to the z-axis) can be from 25 microns to 50 microns, from 50 microns to 100 microns, from 100 microns to 500 microns, or any ranges formed by these values or possibly larger or smaller. Accordingly, a longitudinal distance 708 between an end of the support layer 702 near the active port 106 and the active port 106 can be from 0 to 10 microns, from 10 to 20 microns, from 20 to 50 microns, or any ranges formed by these values or possibly larger or smaller.

In some examples, a width of the edge region of the active layer 711 may have a width (W) substantially equal to a width (W_{c}) of the active chip 701. In some such examples, the width of the support layer 702 (along or parallel to the y-axis) can be substantially equal to the width of the edge region and the width of the active chip 701.

As mentioned above, the optical properties of the support layer 702 may be configured to allow imaging regions near or at the active port 106, and/or positioning the waist of the focused light beam 130 near the active port 106 without being distorted by the active layer 702 such that positioning cannot be performed. As such the focused light beam 130 may be used to fabricate the PW 104 in the presence of the support layer 702 (e.g., a polymer layer).

FIG. 7B schematically illustrates a top view (substrate layer side) of a wafer 720 comprising several active chips similar to the active chip 701 having patterned substrate layers with support layers. The wafer 720 may comprise an active layer 711 including a plurality of active waveguides 710 extending along a longitudinal direction (e.g., parallel to the z-axis), and a patterned substrate layer 119 above the active layer 711. A thickness of a longitudinal etched region 712 of the patterned substrate layer 119 is at least 10%, 15%, 20%, 30%, 40%, or 50% less than the thickness of the substrate layer outside of the longitudinal etched region 712 or any range formed by any of these values or possible larger or smaller. A first support layer 702 is disposed on a first region of the longitudinal etched region 712, and a second support layer 703 is disposed on a second region of the longitudinal etched region 712 leaving a third region 706 of the longitudinal etched region 712, uncovered. In some cases, a length of the first support layer 702 can be substantially equal to that of the second support layer 703. A length of the third region 706 (e.g., along or parallel to the z-axis), can be from 10 to 25 microns, from 25 to 50 microns, from 50 to 200 microns, or any ranges formed by these values or possibly larger or smaller. In some cases, the length of the third region 706 (e.g., along or parallel to the z-axis) can be two times the length 708 of the uncovered region of the active layer 711 of an individual active chip (e.g., the active chip 711) below the longitudinal etched region 712.

In the example shown, the wafer 720 can be divided into a plurality of lateral wafer sections where an individual lateral wafer section is defined by two consecutive longitudinal cleave lines 514, or a longitudinal cleave line and a lateral edge of the wafer. An individual lateral wafer section includes two active wafers and an etched region 712. In some cases, the lateral cleave line 508 may divide the individual lateral etched regions and the individual active waveguides 506 to first and second etched portions, and first and second waveguide portions. In some cases, the individual active chips (e.g., 12 active chips in this case) having a patterned substrate layer 119 mechanically supported by a support layer 702, 703, may be separated from the wafer 720 by cleaving the wafer 720 along a lateral cleave line 508, and along longitudinal cleave lines 514.

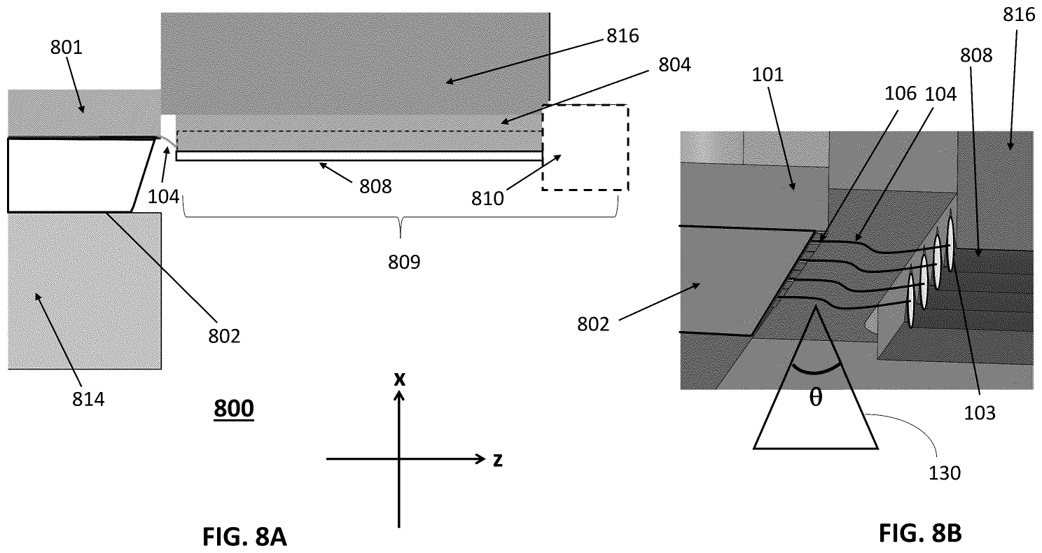

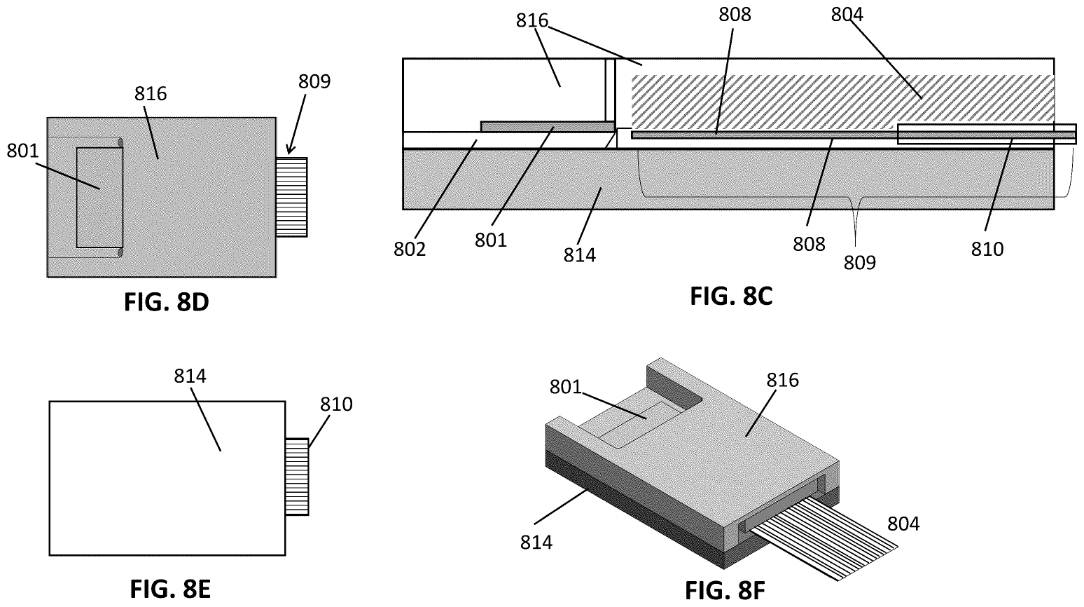

FIG. 8A illustrates a side view of an optical assembly 800 formed by an active chip 801, comprising an array of active waveguides, mounted on a tailored carrier chip 802 in a p-side down configuration, and an optical fiber array 809, where the individual active waveguides of the active chip 801 are optically connected to the respective individual optical fibers of optical fiber array 809, by a plurality of photonic wires. In some cases, an individual active waveguide optically connected to an individual optical fiber in the optical assembly 800 may comprise one or more features described above with respect to the active waveguide 114 of the active chip 101 and the optical device 102 in configuration 230 in FIG. 2D.

In some implementations, the active layer of the active chip 801 can be disposed between a substrate layer of the active chip 801 and the tailored carrier chip 802. In some such cases, the active layer of the active chip 801 may be in thermal contact with the tailored carrier chip 802 directly or via an intermediate layer (e.g., a conductive intermediate layer such as the conductive layer 124), and the tailored carrier chip 802 may be attached to a bottom section 814 of the optical assembly 800.

The optical fiber array 809 may comprise an optical fiber mount 804 comprising a V-groove array configured for aligning the plurality of optical fibers substantially parallel to a longitudinal direction (e.g., parallel to the z-axis). The optical fiber mount 804 may be attached to or mounted on a top section 816 of the optical assembly 800. An optical fiber of the plurality of optical fibers may comprise an optical fiber waveguide 808 (having a core and a cladding layer) and a buffer 810 around the optical fiber waveguide 808. A portion of the buffer 810 covering a section of the optical fiber waveguide 808 placed with a V-groove may be removed such that the optical fiber waveguide 808 is in direct contact with the V-groove.

In some implementations, the tailored carrier chip 802 may be attached to the top section 816 of the optical assembly 800, e.g., via a side wall of the tailored carrier chip 802 and an internal wall of the top section 816 of the optical assembly 800, the side wall and the internal wall being parallel to the x-z plane. In some such implementations, the bottom section 814 of the optical assembly 800 may be connected to the bottom (major) surface of the tailored carrier chip 802 after fabricating the photonic wires between the active waveguides and the optical fibers.

FIG. 8B illustrates a three-dimensional close-up view of the four active waveguides of the active chip 801 optically connected to four optical fibers of the optical fiber array 809 by four respective photonic wires 104. In some cases, the photonic wires 104 may be fabricated using the configuration 230 described with respect to FIG. 2D where a chamfered edge of the carrier chip 802 and the placement of the optical fiber mounted 804 are configured to allow the focused light beam 130 to move to, e.g., the active port 106 to device port 103 to fabricate the PW 104 without optically interfering with any portion of the optical assembly 800. As shown in FIG. 8B, the photonic wires 104 may be fabricated before attaching the bottom (major) section 814 of the optical assembly 800 to the tailored carrier chip 802.

FIG. 8C illustrates a side cross-sectional view of the optical assembly 800 (e.g., an optical connector assembly), shown in FIGS. 8A and 8B, which is used to provide optical connection between the active waveguides of the active chip 801 and the optical fibers of the optical fiber array 809 via a plurality of photonic wires 104. FIG. 8D-8F illustrate a top view, a bottom view, and a 3D perspective view of the optical assembly 800 shown in FIG. 8C, respectively. In some cases, fabrication of the optical assembly 800 may comprise: mounting the active chip 801 on the tailored carrier chip 802, attaching the carrier chip 802 and the fiber optic array (e.g., optical fiber array) 809 to the top section 816 of the optical assembly 800, optically connecting the active waveguides of the active chip 801 to the optical fibers of the optical fiber array 809 by fabricating the PWs between individual active waveguides and individual optical fibers, and attaching the bottom section 814 of the optical assembly 800 to the top section 816 of the optical assembly 800 to enclose the photonic wires is a chamber formed by the top and the bottom sections 814, 816 and thereby protecting the photonic wires from external environment. Other methods of fabricating and other structures, however, are possible.

### EXAMPLE EMBODIMENTS

Some additional nonlimiting examples of embodiments discussed above are provided below. These should not be read as limiting the breadth of the disclosure in any way.

### Example Embodiment 1

Example 1. An optical system comprising an active optical chip optically connected to an optical device via a photonic wire, wherein the active optical chip is mounted on a carrier chip, the active optical chip comprising:
a substrate layer;
an active layer between the substrate layer and the carrier chip, wherein a major surface of the active layer comprises an edge region;
an active waveguide within the active layer, the active waveguide having an active port connected to a first end of the photonic wire, wherein the active waveguide is extended in a longitudinal direction from the active port away from active port;
wherein the edge region is extended in the longitudinal direction from the active port away from the active port, and in a lateral direction, perpendicular to the longitudinal direction and parallel to a major surface of the active layer, from the active waveguide toward two opposite lateral edges of the active layer; and
wherein a thickness or an average thickness of an etched region of the substrate layer above the edge region of the active layer, along a vertical direction perpendicular to the longitudinal and the lateral directions, is smaller than a thickness or an average thickness of other regions of the substrate layer by at least 15%.
Example 2. The optical system of Example 1, wherein the active layer is in thermal contact with the carrier chip.
Example 3. The optical system of any one of Examples 1 or 2, further comprising a conductive layer between the active layer and the carrier chip.
Example 4. The optical system of any one of Example 1 or 2, further comprising an intermediate layer between the active layer and the carrier chip.
Example 5. The optical system of Example 4, wherein the intermediate layer comprises a conductive material.
Example 6. The optical system of any one of the Examples above, wherein a width of the edge region along the lateral direction is equal to a lateral width of the active chip.
Example 7. The optical system of any one of the Examples above, wherein the active optical chip further comprises a support layer disposed above at least a portion of the edge region.
Example 8. The optical system of Example 7, wherein the support layer comprises a polymer.
Example 9. The optical system of Example 8, wherein the polymer comprises SU8.
Example 10. The optical system of any one of the Examples above, wherein a length of the edge region along the longitudinal direction is larger than 25% of a thickness of the substrate layer away from the etched portion of the substrate.
Example 11. The optical system of any one of the Examples above, wherein a width of the edge region along the lateral direction is larger than 100 micrometers.
Example 12. The optical system of any of the Examples above, wherein the thickness or an average thickness of the etched region of the substrate layer above the edge region of the active layer is configured to allow a beam of light output by a laser of a laser based photonic wire bonder to be focused on the active port such that less than 20% of the optical power of the beam of light is incident on the substrate layer.
Example 13. The optical system of Example 12, wherein a vertical distance between a waist of the focused beam of light and an output aperture of an optical head that generates the focused beam of light is smaller than 500 micrometers.
Example 14. The optical system of Example 12 13, wherein a convergence angle of the focused beam of light is larger than 90 degrees.
Example 15. The optical system of any one of the Examples 1, wherein the active chip comprises at least one etch stop layer configured to limit an etching process used to form the etched region.
Example 16. The optical system of Example 15, wherein the etch stop layer comprises one of InGaAsP, InP, GaAs, InGaAs, or InGaP.
Example 17. The optical system of Example 15 or 16, wherein the etch stop layer is at an interface between the active layer and the substrate layer.
Example 18. The optical system of Example 15 or 16, wherein the etch stop layer is within the substrate layer.
Example 19. The optical system of any one of the Examples above, wherein the optical device is mounted on the carrier chip and a second end of the photonic wire is connected to a device port of the optical device, wherein the device port provides optical access to a waveguide of the optical device.
Example 20. The optical system of Example 19, wherein a middle region of the carrier chip extended in the longitudinal direction between the active port and the device port has a thickness, in the vertical direction, smaller than a thickness of the carrier chip outside of the middle region by at least 10 microns.
Example 21. The optical system of any one of the Examples above, wherein an area of the edge region is determined based at least in part on thickness of the substrate layer along the vertical direction.
Example 22. The optical system of any one of the Examples above, wherein the edge region is symmetrically extended in the lateral direction with respect to the active waveguide.
Example 23. The optical system of any one of the Examples above, wherein optical device comprises an optical waveguide and a second end of the photonic wire is connected to a device port of the optical device, wherein the device port provides optical access to the optical waveguide.
Example 24. The optical system of any one of the Examples above, wherein the thickness or the average thickness of the etched region of the substrate layer above the edge region of the active layer is smaller than a thickness or an average thickness of other regions of the substrate layer by at least 50%.
Example 25. The optical system of any one of the Examples above, wherein the thickness or the average thickness of the etched region of the substrate layer above the edge region of the active layer is zero.

### Example Embodiment 2

Example 1. An optical system comprising an active optical chip optically connected to an optical device via a photonic wire, wherein the active optical chip and the optical device are mechanically connected to a common frame, the active optical chip comprising:
a substrate layer;
an active layer between the substrate layer and a carrier chip,
an active waveguide within the active layer, the active waveguide having an active port attached to a first end of the photonic wire, wherein the active waveguide is extended in a longitudinal direction from the active port away from the active port;
wherein an end of the carrier chip closer to the active port, comprises a chamfered edge.
Example 2. The optical system of Example 1, wherein the active layer is in thermal contact with the carrier chip.
Example 3. The optical system of any one of Examples 1 or 2, further comprising a conductive layer between the active layer and the carrier chip.
Example 4. The optical system of any one of Examples 1 or 2, further comprising an intermediate layer between the active layer and the carrier chip.
Example 5. The optical system of Example 4, wherein the intermediate layer comprises a conductive material.
Example 6. The optical system of any one of the Examples above, wherein optical device comprises an optical waveguide and a second end of the photonic wire is connected to a device port of the optical device, wherein the device port provides optical access to the optical waveguide.
Example 7. The optical system of any one of the Examples above, wherein the chamfered edge is configured to allow a beam of light output by a laser of a laser based photonic wirer bonder to be focused on the active port such that less than 20% of the optical power of the beam of light is incident on the carrier chip.
Example 8. The optical system of Example 7, wherein a vertical distance between a waist of the focused beam of light and an output aperture of an optical head that generates the focused beam of light is smaller than 500 micrometers.
Example 9. The optical system of Example 7 or 8, wherein a convergence angle of the focused beam of light is larger than 90 degrees.
Example 10. The optical system of any one of the Examples above, wherein the carrier chip is attached to a bottom portion of the common frame.
Example 11. The optical system of any one of the Examples above, wherein the optical device is attached to a top portion of the common frame.
Example 12. The optical system of any one of the Examples above, wherein the optical device comprises an optical fiber mounted on second carrier chip.

### Example Embodiment 3

Example 1. An optical system comprising an active optical chip optically connected to an optical device via a photonic wire, wherein the active optical chip is mounted on a carrier chip, the active optical chip comprising:
a substrate layer;
an active layer between the substrate layer and the carrier chip, wherein a major surface of the active layer comprises an edge region; and
an active waveguide within the active layer, the active waveguide having an active port closer to the edge region, the active port connected to a first end of the photonic wire, wherein the active waveguide is extended in a longitudinal direction from the active port away from active port;
wherein a thickness of an end of the carrier chip closer to the active port or a thickness of the substrate layer above the edge region is configured to allow a waist of a focused light beam to be positioned at the active port without optically interfering with any portion of the carrier chip or the substrate layer, respectively.
Example 2. The optical system of Example 1, wherein the edge region is extended in the longitudinal direction from the active port away from the active port, and in a lateral direction, perpendicular to the longitudinal direction and parallel to a major surface of the active layer, from the active waveguide toward two opposite lateral edges of the active layer; and wherein a thickness or an average thickness of an etched portion of the substrate layer above the edge region of the active layer, along a vertical direction perpendicular to the longitudinal and the lateral directions, is smaller than a thickness or an average thickness of other regions of the substrate layer by at least 15%.
Example 3. The optical system of Example 1, wherein the end of the carrier chip comprises a chamfered edge.
Example 4. The optical system of Example 1, wherein the active layer is in thermal contact with the carrier chip.
Example 5. The optical system of Example 1, further comprising an intermediate layer between the active layer and the carrier chip.
Example 6. The optical system of Example 5, wherein the intermediate layer comprises a conductive material.
Example 7. The optical system of Example 2, wherein a length of the edge region along the longitudinal direction is larger than 25% of a thickness of the substrate layer away from the etched portion of the substrate layer.
Example 8. The optical system of Example 1, wherein a vertical distance between the waist of the focused beam of light and an output aperture of an optical head that generates the focused beam of light is smaller than 500 micrometers.
Example 9. The optical system of Example 1, wherein a convergence angle of the focused beam of light is larger than 30 degrees.
Example 10. The optical system of Example 1, wherein the optical device is mounted on the carrier chip and a second end of the photonic wire is connected to a device port of the optical device, wherein the device port provides optical access to a waveguide of the optical device.
Example 11. The optical system of Example 10, wherein a middle region of the carrier chip extended in the longitudinal direction between the active port and the device port has a thickness, in the vertical direction, smaller than a thickness of the carrier chip outside of the middle region by at least 10 microns.
Example 12. The optical system of Example 1, wherein an area of the edge region is determined based at least in part on thickness of the substrate layer along the vertical direction.
Example 13. The optical system of Example 1, wherein optical device comprises an optical waveguide and a second end of the photonic wire is connected to a device port of the optical device, wherein the device port provides optical access to the optical waveguide.
Example 14. An optical system comprising an active optical chip optically connected to an optical device via a photonic wire, wherein the active optical chip and the optical device are mechanically connected to a common frame, the active optical chip comprising:
a substrate layer;
an active layer between the substrate layer and a carrier chip; and
an active waveguide within the active layer, the active waveguide having an active port attached to a first end of the photonic wire, wherein the active waveguide is extended in a longitudinal direction from the active port away from the active port;
wherein a thickness of an end region of the carrier chip closer to the active port is configured to allow a waist of a focused light beam to be positioned at the active port without optically interfering with any portion of the carrier chip or the substrate layer.
Example 15. The optical system of Example 14, wherein the end of the carrier chip comprises a chamfered edge.
Example 16. The optical system of Example 14, wherein the active layer is in thermal contact with the carrier chip.
Example 17. The optical system of Example 14, wherein optical device comprises an optical waveguide and a second end of the photonic wire is connected to a facet of the optical waveguide to provide optical access to the optical waveguide.
Example 18. The optical system of Example 14 wherein the thickness of the end region of the carrier chip is configured to allow a beam of light output by a laser of a laser based photonic wire bonder to be focused on the active port such that less than 20% of the optical power of the beam of light is incident on the carrier chip.
Example 19. The optical system of any of Example 14, wherein the optical device comprises an optical fiber mounted on second carrier chip.
Example 20. A method of fabricating an optical assembly, the method comprising:
providing an active photonic chip having an active layer and a substrate;
providing a fiber optic array;
mounting the active photonic chip on a tailored carrier chip such that the active layer is between the substrate and the carrier chip;
mechanically connecting the carrier chip and the fiber optic array to a common frame; and
optically connecting active waveguides of the active layer to the optical fibers of the optical fiber array by fabricating photonic wires between individual active waveguides and individual optical fibers.

### Terminology

A major surface of a layer or chip (e.g., active layer, substrate layer, or carrier chip) can be a top surface or bottom surface of the layer or the chip where a thickness of the layer of the chip along a direction perpendicular to the major surface is smaller than a width or length of the major surface. The major surface can have a rectangular shape or any shape having a plurality of edges.

It should be understood that in various designs and implementations described above thermal contact includes direct contact, contact via one or more intermediate layers (e.g., metallic or dielectric layers), some of which can be thermally conductive layers.

Conditional language, such as “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements, and/or steps are in any way required for one or more embodiments.

Conjunctive language such as the phrase “at least one of X, Y, and Z,” unless specifically stated otherwise, is to be understood within the context used in general to convey that an item, term, etc. may be either X, Y, or Z. Thus, such conjunctive language is not generally intended to imply that certain embodiments require the presence of at least one of X, at least one of Y, and at least one of Z.

Language of degree, as used herein, such as the terms “approximately,” “about,” “generally,” and “substantially,” represent a value, amount, or characteristic close to the stated value, amount, or characteristic that still performs a desired function or achieves a desired result. For example, the terms “approximately,” “about,” “generally,” and “substantially” may refer to an amount that is within +10% of, within +5% of, within +2% of, within +1% of, or within +0.1% of the stated amount. As another example, the terms “generally parallel” and “substantially parallel” refer to a value, amount, or characteristic that departs from exactly parallel by +10 degrees, by +5 degrees, by +2 degrees, by +1 degree, or by +0.1 degree, and the terms “generally perpendicular” and “substantially perpendicular” refer to a value, amount, or characteristic that departs from exactly perpendicular by +10 degrees, by +5 degrees, by +2 degrees, by +1 degree, or by +0.1 degree.

Various configurations have been described above. Although this invention has been described with reference to these specific configurations, the descriptions are intended to be illustrative of the invention and are not intended to be limiting. Various modifications and applications may occur to those skilled in the art without departing from the true spirit and scope of the invention. Thus, for example, in any method or process disclosed herein, the acts or operations making up the method/process may be performed in any suitable sequence and are not necessarily limited to any particular disclosed sequence. Features or elements from various embodiments and examples discussed above may be combined with one another to produce alternative configurations compatible with embodiments disclosed herein. Various aspects and advantages of the embodiments have been described where appropriate. It is to be understood that not necessarily all such aspects or advantages may be achieved in accordance with any particular embodiment. Thus, for example, it should be recognized that the various embodiments may be carried out in a manner that achieves or optimizes one advantage or group of advantages as taught herein without necessarily achieving other aspects or advantages as may be taught or suggested herein.

What is claimed is:

1. An optical system comprising an active optical chip optically connected to an optical device via a photonic wire, wherein the active optical chip is mounted on a carrier chip, the active optical chip comprising:
a substrate layer;
an active layer between the substrate layer and the carrier chip, wherein a major surface of the active layer comprises an edge region; and
an active waveguide within the active layer, the active waveguide having an active port closer to the edge region, the active port connected to a first end of the photonic wire, wherein the active waveguide is extended in a longitudinal direction from the active port away from active port;
wherein a thickness of an end of the carrier chip closer to the active port or a thickness of the substrate layer above the edge region is configured to allow a waist of a focused light beam to be positioned at the active port without optically interfering with any portion of the carrier chip or the substrate layer, respectively.

2. The optical system of claim 1, wherein the edge region is extended in the longitudinal direction from the active port away from the active port, and in a lateral direction, perpendicular to the longitudinal direction and parallel to a major surface of the active layer, from the active waveguide toward two opposite lateral edges of the active layer; and wherein a thickness or an average thickness of an etched portion of the substrate layer above the edge region of the active layer, along a vertical direction perpendicular to the longitudinal and the lateral directions, is smaller than a thickness or an average thickness of other regions of the substrate layer by at least 15%.

3. The optical system of claim 1, wherein the end of the carrier chip comprises a chamfered edge.

4. The optical system of claim 1, wherein the active layer is in thermal contact with the carrier chip.

5. The optical system of claim 1, further comprising an intermediate layer between the active layer and the carrier chip.

6. The optical system of claim 5, wherein the intermediate layer comprises a conductive material.

7. The optical system of claim 2, wherein a length of the edge region along the longitudinal direction is larger than 25% of a thickness of the substrate layer away from the etched portion of the substrate layer.

8. The optical system of claim 1, wherein a vertical distance between the waist of the focused beam of light and an output aperture of an optical head that generates the focused beam of light is smaller than 500 micrometers.

9. The optical system of claim 1, wherein a convergence angle of the focused beam of light is larger than 30 degrees.

10. The optical system of claim 1, wherein the optical device is mounted on the carrier chip and a second end of the photonic wire is connected to a device port of the optical device, wherein the device port provides optical access to a waveguide of the optical device.

11. The optical system of claim 10, wherein a middle region of the carrier chip extended in the longitudinal direction between the active port and the device port has a thickness, in the vertical direction, smaller than a thickness of the carrier chip outside of the middle region by at least 10 microns.

12. The optical system of claim 1, wherein an area of the edge region is determined based at least in part on thickness of the substrate layer along the vertical direction.

13. The optical system of claim 1, wherein optical device comprises an optical waveguide and a second end of the photonic wire is connected to a device port of the optical device, wherein the device port provides optical access to the optical waveguide.

14. An optical system comprising an active optical chip optically connected to an optical device via a photonic wire, wherein the active optical chip and the optical device are mechanically connected to a common frame, the active optical chip comprising:
a substrate layer;
an active layer between the substrate layer and a carrier chip; and
an active waveguide within the active layer, the active waveguide having an active port attached to a first end of the photonic wire, wherein the active waveguide is extended in a longitudinal direction from the active port away from the active port;
wherein a thickness of an end region of the carrier chip closer to the active port is configured to allow a waist of a focused light beam to be positioned at the active port without optically interfering with any portion of the carrier chip or the substrate layer.

15. The optical system of claim 14, wherein the end of the carrier chip comprises a chamfered edge.

16. The optical system of claim 14, wherein the active layer is in thermal contact with the carrier chip.

17. The optical system of claim 14, wherein optical device comprises an optical waveguide and a second end of the photonic wire is connected to a facet of the optical waveguide to provide optical access to the optical waveguide.

18. The optical system of claim 14, wherein the thickness of the end region of the carrier chip is configured to allow a beam of light output by a laser of a laser based photonic wire bonder to be focused on the active port such that less than 20% of the optical power of the beam of light is incident on the carrier chip.

19. The optical system of any of claim 14, wherein the optical device comprises an optical fiber mounted on second carrier chip.

20. A method of fabricating an optical assembly, the method comprising:
providing an active photonic chip having an active layer and a substrate;
providing a fiber optic array;
mounting the active photonic chip on a tailored carrier chip such that the active layer is between the substrate and the carrier chip;
mechanically connecting the carrier chip and the fiber optic array to a common frame; and
optically connecting active waveguides of the active layer to the optical fibers of the optical fiber array by fabricating photonic wires between individual active waveguides and individual optical fibers.
